(19) United States
(12) Patent Application Publication
(10) Pub. No.: US 2026/0304806 A1
(43) Pub. Date: Oct. 1, 2026

(54) SEMICONDUCTOR DEVICE

(71) Applicant: Renesas Electronics Corporation, Tokyo (JP)

(72) Inventors: Tomohiro IMAI, Tokyo (JP); Atsushi SAKAI, Tokyo (JP)

(21) Appl. No.: 19/530,976

(22) Filed: Feb. 5, 2026

(30) Foreign Application Priority Data
Mar. 27, 2025 (JP) 2025-052944

(51) Int. Cl. H10D 8/60; H10D 62/10; H10D 62/60

(52) U.S. Cl. CPC H10D 8/60; H10D 62/103; H10D 62/126; H10D 62/60

(57) ABSTRACT

A semiconductor device includes a semiconductor substrate having an upper surface, a first semiconductor region and a second semiconductor region formed at the upper surface of the semiconductor substrate, a first buried region disposed under the first semiconductor region and the second semiconductor region, a first region formed in the first semiconductor region and disposed at the upper surface of the semiconductor substrate, a cathode region formed in the second semiconductor region and disposed at the upper surface of the semiconductor substrate, and a first insulating region disposed between the first semiconductor region and the cathode region. An impurity concentration of the second semiconductor region is higher than an impurity concentration of the first semiconductor region. In cross-sectional view, the second semiconductor region reaches a side surface of the first insulating region facing the first semiconductor region.

### CROSS-REFERENCE TO RELATED APPLICATIONS

The disclosure of Japanese Patent Application No. 2025-052944 filed on Mar. 27, 2025, including the specification, drawings and abstract is incorporated herein by reference in its entirety.

### BACKGROUND

The present disclosure relates to a semiconductor device, particularly to a semiconductor device having a Schottky barrier diode.

A Schottky Barrier Diode (SBD) is a rectifier element that utilizes the Schottky barrier formed by the junction of metal and semiconductor. Compared to diodes utilizing PN junctions, SBDs have lower forward voltage characteristics and faster switching speeds. On the other hand, SBDs have the issue of having a larger leakage current than diodes utilizing PN junctions.

There are disclosed techniques listed below.
[Patent Document 1] Japanese Unexamined Patent Application Publication No. 2006-310555

Patent Document 1 discloses an SBD including a semiconductor region, an anode electrode, a guard ring formed along the periphery of the anode electrode, an insulating film separating the anode electrode formed around the guard ring, and a mask for the anode electrode. The semiconductor region and the guard ring have opposite conductivity types. Such a configuration can reduce the reverse leakage current of the SBD.

### SUMMARY

The breakdown voltage of the SBD described in Patent Document 1 depends on the lateral length of the substrate. In the reverse bias state, the electric field of the SBD may not only concentrate at the corners of the Schottky electrode but also reach directly under the Schottky electrode. Therefore, when considering size reduction, there is a challenge in securing the breakdown voltage of the SBD.

Other objects and novel features will become apparent from the description of this specification and the accompanying drawings.

According to one embodiment of the semiconductor device of the present disclosure, by spreading the potential in the depth direction of the substrate to secure breakdown voltage and forming offset regions with different conductivity types between the Schottky region and the cathode region, the driving voltage of the SBD can be reduced.

The present disclosure can provide a compact semiconductor device that achieves high breakdown voltage, low driving voltage, and low leakage current.

### BRIEF DESCRIPTION OF THE DRAWINGS

FIG. 1 is a cross-sectional view of a semiconductor device of a first embodiment.

FIG. 2 is a cross-sectional view of the semiconductor device of the first embodiment.

FIG. 3A is a diagram showing the driving voltage and leakage current of the semiconductor device of the first embodiment.

FIG. 3B is a diagram showing the driving voltage and leakage current of the semiconductor device of the first embodiment.

FIG. 4A is a diagram showing the electrostatic potential map of the semiconductor device of the first embodiment in reverse bias.

FIG. 4B is a diagram showing the impact ion distribution of the semiconductor device of the first embodiment in reverse bias.

FIG. 5 is a diagram showing the electrostatic potential map of the semiconductor device of the comparative example in reverse bias.

FIG. 6A is a diagram showing the relationship between the offset amount and the driving voltage of the semiconductor device of the first embodiment.

FIG. 6B is a diagram showing the relationship between the offset amount and the leakage current of the semiconductor device of the first embodiment.

FIG. 7A is a plan view of the semiconductor device of the first embodiment.

FIG. 7B is a plan view of the semiconductor device of the first embodiment.

FIG. 8 is a cross-sectional view of the semiconductor device of a second embodiment.

FIG. 9A is a plan view of the semiconductor device of the second embodiment.

FIG. 9B is a plan view of the semiconductor device of the second embodiment.

FIG. 10A is a diagram showing the driving voltage and leakage current of the semiconductor device of the second embodiment.

FIG. 10B is a diagram showing the driving voltage and leakage current of the semiconductor device of the second embodiment.

FIG. 11A is a diagram showing the relationship between the offset amount and the driving voltage and leakage current of the semiconductor device of the second embodiment.

FIG. 11B is a diagram showing the relationship between the offset amount and the driving voltage and leakage current of the semiconductor device of the second embodiment.

FIG. 12A is a cross-sectional view of a semiconductor device of a third embodiment.

FIG. 12B is a cross-sectional view of the semiconductor device of the third embodiment.

FIG. 13 is a cross-sectional view of the semiconductor device of the third embodiment.

FIG. 14 is a cross-sectional view of a semiconductor device of a fourth embodiment.

FIG. 15A is a plan view of a semiconductor device of a fifth embodiment.

FIG. 15B is a plan view of the semiconductor device of the fifth embodiment.

FIG. 15C is a plan view of the semiconductor device of the fifth embodiment.

FIG. 15D is a plan view of the semiconductor device of the fifth embodiment.

FIG. 16A is a plan view of the semiconductor device of the fifth embodiment.

FIG. 16B is a plan view of the semiconductor device of the fifth embodiment.

FIG. 16C is a plan view of the semiconductor device of the fifth embodiment.

FIG. 17 is a cross-sectional view of a semiconductor device of a first comparative example.

FIG. 18 is a cross-sectional view of a semiconductor device of second comparative example.

### DETAILED DESCRIPTION

Hereinafter, embodiments of the present disclosure will be described in detail with reference to the drawings. In the specification and the drawings, the same or corresponding components are denoted by the same reference numerals, and repetitive descriptions thereof may be omitted. In the drawings, for convenience of description, the configuration may be omitted or simplified. Also, at least some of the embodiments may be arbitrarily combined with each other.

In the semiconductor device of the present disclosure, the conductivity type (p-type or n-type) of the semiconductor substrate, semiconductor region, diffusion region, transistor, etc., may be inverted. In the case where one of the conductivity types of the n-type or the p-type is the first conductivity type and the other conductivity type is the second conductivity type, the first conductivity type can be the p-type and the second conductivity type can be the n-type, or on the contrary, the first conductivity type can be the n-type and the second conductivity type can be the p-type.

In the following embodiments, for convenience, the first conductivity type will be described as p-type and the second conductivity type as n-type.

The impurity concentration of the components included in the semiconductor device of the present disclosure refers to the peak value in the measured region of the component. Also, when the impurity concentrations of two components are compared and described as “similar”, it does not mean that they are completely identical. Even if the impurity concentrations of two components differ due to manufacturing variations, if the set values of the impurity concentrations of the two components are the same, the impurity concentrations of the two components are considered to be the same.

### First Embodiment

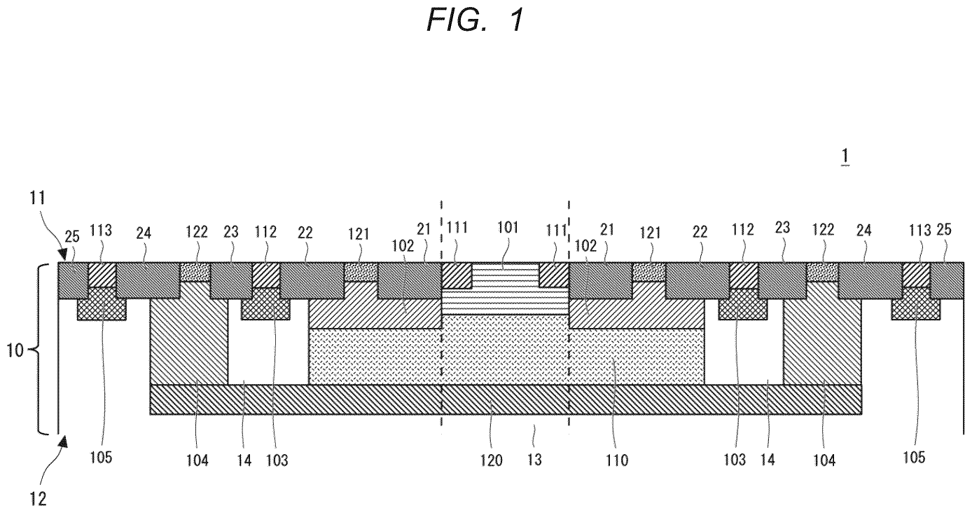

FIG. 1 is a cross-sectional view of the semiconductor device 1 of the present disclosure. The semiconductor device 1 includes a semiconductor substrate 10 having a first conductivity type, which is p-type, and a plurality of regions formed in the semiconductor substrate 10. The semiconductor substrate 10 may be a laminate including a substrate body and an epitaxial layer formed on the substrate body. The laminate corresponds to the first semiconductor layer 13 and the second semiconductor layer 14, which will be described later.

Examples of the semiconductor device 1 include a semiconductor chip including a Schottky Barrier Diode (SBD), a semiconductor wafer, and a package in which these are mounted.

The semiconductor substrate 10 has an upper surface 11 and a lower surface 12.

The first semiconductor region 101, having a second conductivity type, which is n-type, opposite to the first conductivity type, is formed in the semiconductor substrate 10 and at the upper surface 11 of the semiconductor substrate 10. The first semiconductor region 101 is formed, for example, by introducing impurities indicating the second conductivity type, which is n-type, into the semiconductor substrate 10. The first semiconductor region 101 functions as the anode region of the SBD, that is, the Schottky region.

The second semiconductor region 102, having the second conductivity type, which is n-type, is formed in the semiconductor substrate 10. Also, the impurity concentration of the second semiconductor region 102 is, for example, higher than the impurity concentration of the first semiconductor region 101. The depth of the second semiconductor region 102 from the upper surface 11 is greater than the depth of the first semiconductor region 101 from the upper surface 11. The second semiconductor region 102 is formed, for example, by introducing impurities indicating the second conductivity type, which is n-type, into the semiconductor substrate 10.

The first buried region 110, having the first conductivity type, which is p-type, is formed in the semiconductor substrate 10 and is located under the first semiconductor region 101 and the second semiconductor region 102. The first buried region 110 is in contact with the first semiconductor region 101. Also, the impurity concentration of the first buried region 110 is, for example, higher than the impurity concentration of the semiconductor substrate 10. The first buried region 110 is formed, for example, by introducing impurities indicating the first conductivity type, which is p-type, into the semiconductor substrate 10. With such a configuration, the first buried region 110 functions as a potential barrier, suppressing the current path of the SBD from spreading too far downward.

The first region 111, having the first conductivity type, which is p-type, is formed in the semiconductor substrate 10 and is located at the upper surface 11 of the semiconductor substrate 10. Specifically, the first region 111 is formed in the first semiconductor region 101. The depth of the first region 111 from the upper surface 11 is smaller than the depth of the first semiconductor region 101 from the upper surface 11. Also, the impurity concentration of the first region 111 is, for example, higher than the impurity concentration of the semiconductor substrate 10 and the impurity concentration of the first buried region 110. The first region 111 is formed, for example, by introducing impurities indicating the first conductivity type, which is p-type, into the semiconductor substrate 10 after the formation of the first semiconductor region 101. With such a configuration, the first region 111 functions as a potential barrier, preventing the electric field from concentrating at the interface between the Schottky electrode and the first semiconductor region 101 during reverse bias, thereby suppressing leakage current.

The cathode region 121, having the second conductivity type, which is n-type, is formed in the semiconductor substrate 10 and is located at the upper surface 11 of the semiconductor substrate 10. Also, the impurity concentration of the cathode region 121 is, for example, higher than the impurity concentration of the first semiconductor region 101 and the impurity concentration of the second semiconductor region 102. The cathode region 121 is formed, for example, by introducing impurities indicating the first conductivity type, which is n-type, into the semiconductor substrate 10 after the formation of the second semiconductor region 102.

The first insulating region 21 is formed in the semiconductor substrate 10 and is located between the first semiconductor region 101 and the cathode region 121 in the cross-sectional view shown in FIG. 1. The depth of the first insulating region 21 from the upper surface 11 is smaller than the depth of the first semiconductor region 101 from the upper surface 11. The first insulating region 21 functions as an element isolation insulating layer, that is, STI (Shallow Trench Isolation). The first insulating region 21 is formed by forming a trench in the semiconductor substrate 10 and filling an insulating film in the trench before forming the first semiconductor region 101, the second semiconductor region 102, the first region 111, and the cathode region 121 in the semiconductor substrate 10.

Additionally, as shown by the dotted line in FIG. 1, the second semiconductor region 102 reaches the side surface of the first insulating region 21 facing the first semiconductor region 101 in cross-sectional view. That is, in the cross-sectional view of FIG. 1, the side surface of the first semiconductor region 101 is in contact with the side surface of each of the first insulating region 21 and the second semiconductor region 102. With this configuration, the current path of the SBD can be secured, preventing deterioration of the driving voltage.

In addition, in the cross-sectional view of FIG. 1, the second semiconductor region 102 covers the bottom surface of the first insulating region 21 and overlaps the first insulating region 21.

By forming a Schottky electrode (not shown) on the first semiconductor region 101 and a cathode electrode (not shown) on the cathode region 121, the SBD is formed by the first semiconductor region 101 and the second semiconductor region 102. The semiconductor device 1 of this disclosure is a compact SBD that achieves high breakdown voltage, low driving voltage, and low leakage current in the following aspects.

The breakdown voltage of the SBD, which is the semiconductor device 1 of this disclosure, depends on the depth of the second semiconductor region 102 and the depth of the first buried region 110. If the depth of the second semiconductor region 102 is smaller than the depth of the first semiconductor region 101, breakdown occurs at the corners of the first insulating region 21. Therefore, when the upper surface 11 of the semiconductor substrate 10 is used as a reference plane, the depth of the second semiconductor region 102 needs to be greater than the depth of the first insulating region 21 and the depth of the first semiconductor region 101. Also, from the perspective of securing the current path and potential barrier effect, when the upper surface 11 of the semiconductor substrate 10 is used as a reference plane, the depth of the first semiconductor region 101 needs to be greater than the depth of the first insulating region 21.

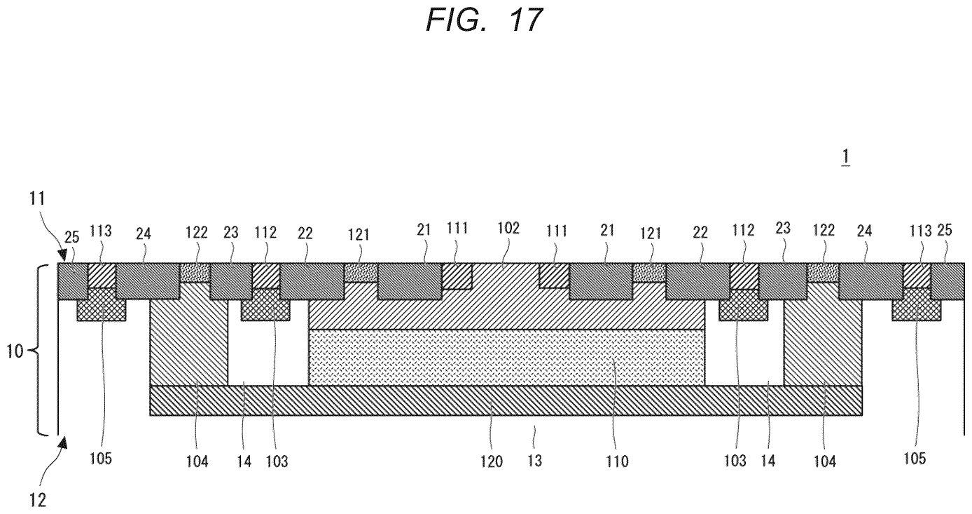

As a first comparative example, the case where the second semiconductor region 102 is formed up to the area where the first semiconductor region 101 is formed without forming the first semiconductor region 101, is considered. FIG. 17 is a cross-sectional view of the semiconductor device of the first comparative example. In the first comparative example, the SBD is formed by a Schottky electrode (not shown), the second semiconductor region 102, and a cathode electrode (not shown). Since the depth of the second semiconductor region 102 is greater than the depth of the first semiconductor region 101, the distance between the first region 111 and the first buried region 110 in the first comparative example becomes larger compared to the distance between the first region 111 and the first buried region 110 in the first embodiment. Therefore, the function of the first region 111 as a potential barrier becomes weaker. Thus, the first semiconductor region 101 located directly under the Schottky electrode needs to be shallower and has a lower impurity concentration than the second semiconductor region 102.

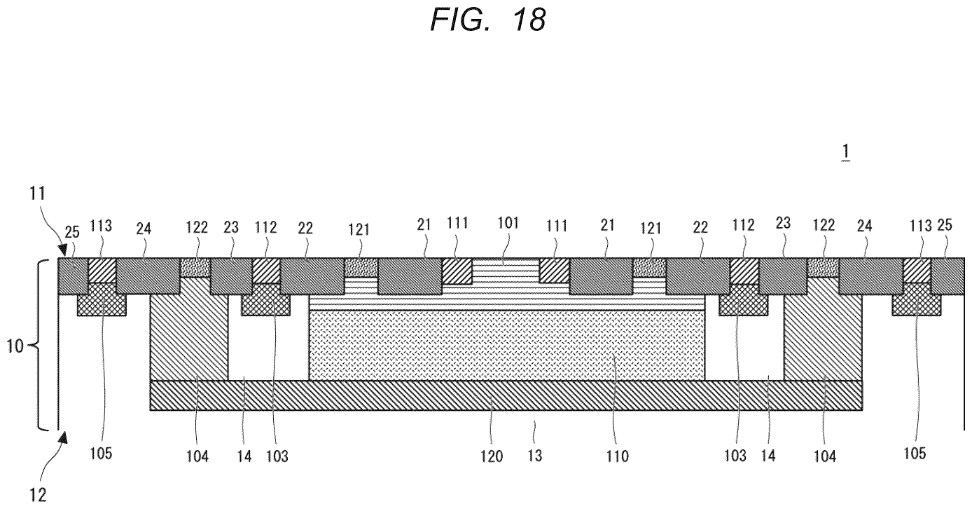

Additionally, as the second comparative example, the case where the first semiconductor region 101 is formed up to the area where the second semiconductor region 102 is formed without forming the second semiconductor region 102 is considered. FIG. 18 is a cross-sectional view of the semiconductor device of the second comparative example. In the second comparative example, the SBD is formed by a Schottky electrode, the first semiconductor region 101, and a cathode electrode. Since the depth of the first semiconductor region 101 is smaller than the depth of the second semiconductor region 102, the depth of the first semiconductor region located under the first insulating region 21 in the second comparative example becomes smaller compared to the depth of the second semiconductor region 102 located under the first insulating region 21 in the first embodiment. Therefore, in the second comparative example, the width of the current path located under the first insulating region 21 becomes smaller, resulting in an increase in the electrical resistance of the current path located under the first insulating region 21. Thus, the driving voltage of the SBD deteriorates. Furthermore, during reverse bias, the first semiconductor region 101 becomes fully depleted, reducing the breakdown voltage of the SBD. Therefore, having the first semiconductor region 101 and the second semiconductor region 102 is important in the SBD.

Also, when the upper surface 11 of the semiconductor substrate 10 is used as a reference plane, it is preferable that the depth of the first region 111 is greater than the depth of the cathode region 121.

The semiconductor device 1 shown in FIG. 1 can further include the following components.

The third semiconductor region 103, which has a p-type first conductivity type, is formed in the semiconductor substrate 10. Additionally, the impurity concentration of the third semiconductor region 103 is, for example, higher than the impurity concentration of the first semiconductor region 101. The third semiconductor region 103 is formed, for example, by introducing impurities indicating a p-type first conductivity type into the semiconductor substrate 10. The third semiconductor region 103 functions as a back gate electrode of the SBD.

The second region 112, which has a p-type first conductivity type, is formed in the semiconductor substrate 10 and is located on the upper surface 11 of the semiconductor substrate 10. Additionally, the impurity concentration of the second region 112 is, for example, about the same as the impurity concentration of the first region 111 and higher than the impurity concentration of the third semiconductor region 103. The second region 112 is formed, for example, by the same process as the first region 111.

The second insulating region 22 is formed in the semiconductor substrate 10 and is located between the cathode region 121 and the second region 112 in the cross-sectional view shown in FIG. 1. The second insulating region 22 functions as an STI. The second insulating region 22 is formed, for example, by the same process as the first insulating region 21.

The fourth semiconductor region 104, which has an n-type second conductivity type, is formed in the semiconductor substrate 10. The fourth semiconductor region 104 functions as a sinker region. Additionally, the impurity concentration of the fourth semiconductor region 104 is, for example, about the same as the impurity concentration of the second semiconductor region 102.

The contact region 122, which has an n-type second conductivity type, is formed in the semiconductor substrate 10 and is located at the upper surface 11 of the semiconductor substrate 10. Additionally, the impurity concentration of contact region 122 is, for example, about the same as the impurity concentration of the cathode region 121. The contact region 122 is formed, for example, by the same process as the cathode region 121.

The third insulating region 23 is formed in the semiconductor substrate 10 and is located between the second region 112 and the contact region 122 in the cross-sectional view shown in FIG. 1. The third insulating region 23 functions as an STI. The third insulating region 23 is formed, for example, by the same process as the first insulating region 21 and the second insulating region 22.

The fifth semiconductor region 105, which has a p-type first conductivity type, is formed in the semiconductor substrate 10. Additionally, the impurity concentration of the fifth semiconductor region 105 is, for example, higher than the impurity concentration of the first semiconductor region 101 and about the same as the impurity concentration of the third semiconductor region 103. The fifth semiconductor region 105 is formed, for example, by the same process as the third semiconductor region 103. The fifth semiconductor region 105 functions as a substrate electrode.

The third region 113, which has a p-type first conductivity type, is formed in the semiconductor substrate 10 and is located at the upper surface 11 of the semiconductor substrate 10. Additionally, the impurity concentration of the third region 113 is, for example, about the same as the impurity concentration of the first region 111 and higher than the impurity concentration of the third semiconductor region 103. The second region 112 is formed, for example, by the same process as the first region 111.

The fourth insulating region 24 is formed in the semiconductor substrate 10 and is located between the contact region 122 and the third region 113 in the cross-sectional view shown in FIG. 1. The fourth insulating region 24 functions as an STI. The fourth insulating region 24 is formed, for example, by the same process as the first insulating region 21, the second insulating region 22, and the third insulating region 23.

The fifth insulating region 25 is formed in the semiconductor substrate 10 and is located outside the third region 113, that is, on the edge side of the semiconductor substrate 10 in the cross-sectional view shown in FIG. 1. The fifth insulating region 25 functions as an STI. The fifth insulating region 25 is formed, for example, by the same process as the first insulating region 21, the second insulating region 22, the third insulating region 23, and the fourth insulating region 24.

The second buried region 120, which has an n-type second conductivity type, is formed in the semiconductor substrate 10 and is located under the first buried region 110 and the sinker region, which is the fourth semiconductor region 104, in the cross-sectional view shown in FIG. 1. Therefore, the second buried region 120 functions to separate other elements formed in the semiconductor substrate 10 from the SBD. Additionally, the impurity concentration of the second buried region 120 is, for example, higher than the impurity concentration of the second semiconductor region 102 and lower than the impurity concentration of the cathode region 121. The second buried region 120 is formed, for example, by introducing impurities indicating an n-type second conductivity type into the semiconductor substrate 10.

Note that the components formed in the semiconductor substrate 10 may be formed in the first semiconductor layer 13 or the second semiconductor layer 14. The manufacturing method of the semiconductor device 1 in this case is as follows. First, epitaxial growth is performed on the semiconductor substrate 10 to form the first semiconductor layer 13. Next, the second buried region 120 is formed in the first semiconductor layer 13. Then, epitaxial growth is performed on the first semiconductor layer 13 to form the second semiconductor layer 14. Then, in the second semiconductor layer 14, the first buried region 110 and regions from the first semiconductor region 101 to the fifth semiconductor region 105 are formed. Note that the method of forming each component in the first semiconductor layer 13 or the second semiconductor layer 14 is similar to the method of forming each component in the semiconductor substrate 10.

Next, a modified example of the above semiconductor device 1 will be described. Note that repetitive descriptions of components similar to those in the configuration example of the above semiconductor device 1 may be omitted.

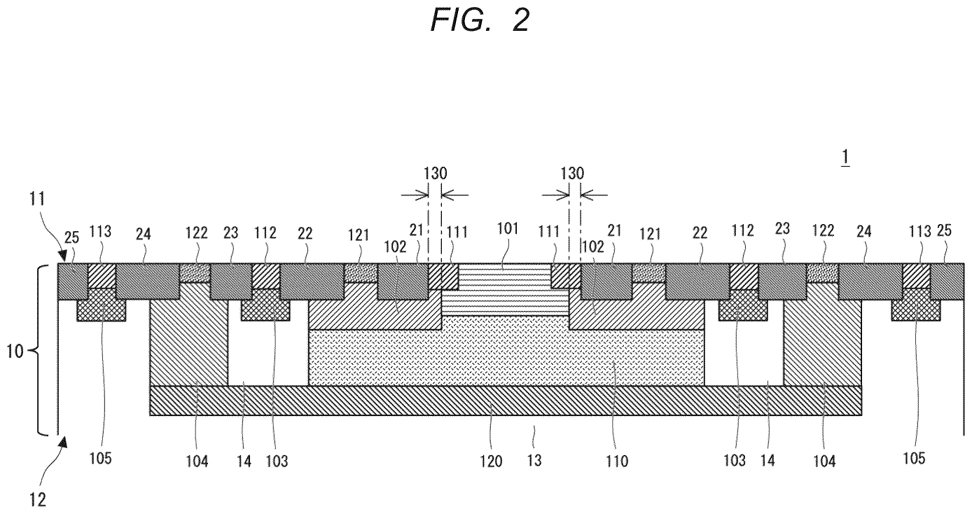

FIG. 2 shows a modified example where the second semiconductor region 102 has an offset region 130 overlapping the first region 111 in plan view. The side surface of the second semiconductor region 102 may not be in contact with the side surface of the first insulating region 21, and the side surface of the second semiconductor region 102 may be located under the first region 111.

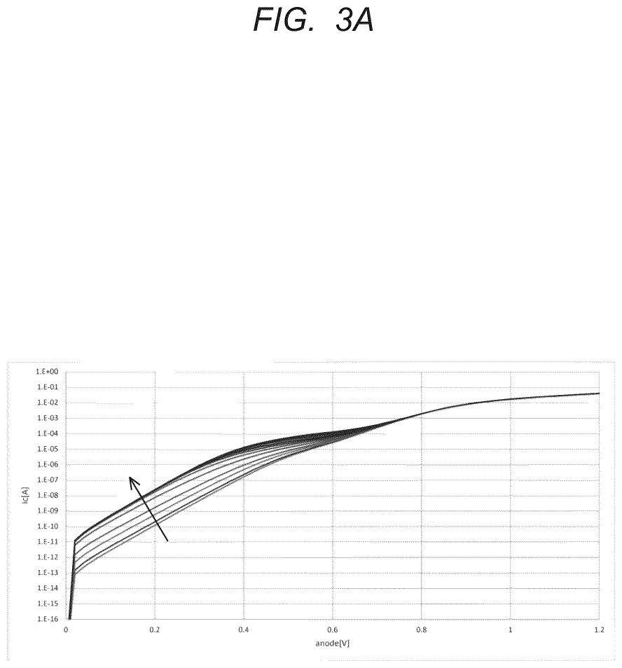

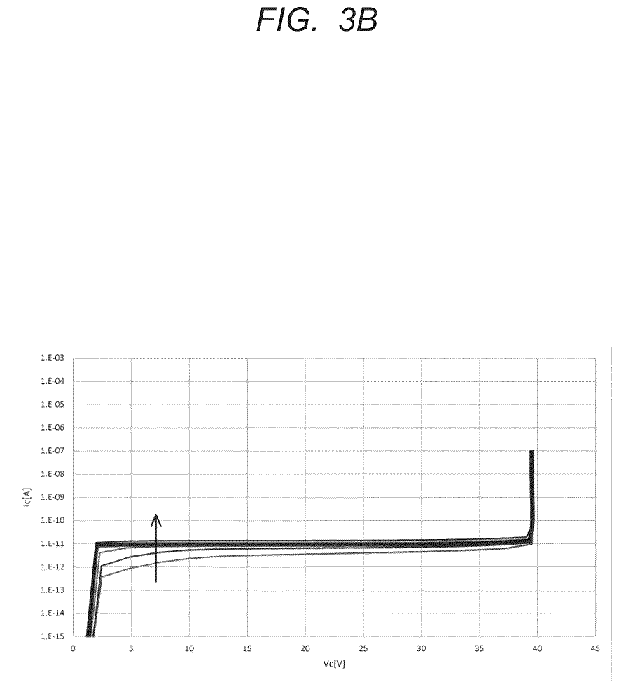

FIG. 3A shows the driving voltage of the semiconductor device 1 of the present disclosure, and FIG. 3B shows the off current, i.e., the leakage current, of the semiconductor device 1 of the present disclosure. FIG. 3A and FIG. 3B each represent the dependency of the offset amount of the driving voltage and the leakage current. The width of the first region 111 of the semiconductor device 1 is set to 1, and the width of the offset region 130 is varied from 0 to 1 to simulate the driving voltage and leakage current of the semiconductor device 1. The arrows in FIG. 3A and FIG. 3B indicate the direction in which the width of the offset region 130 increases from 0 to 1.

As shown in FIG. 3A, as the width of the offset region 130 increases, the driving voltage of the semiconductor device 1 decreases. On the other hand, as shown in FIG. 3B, as the width of the offset region 130 increases, the leakage current of the semiconductor device 1 increases. Thus, if the width of the offset region 130 is too large, the function of the potential barrier of the first region 111 is impaired, but by forming an offset region 130 with an appropriate width, the driving voltage of the semiconductor device 1 can be reduced.

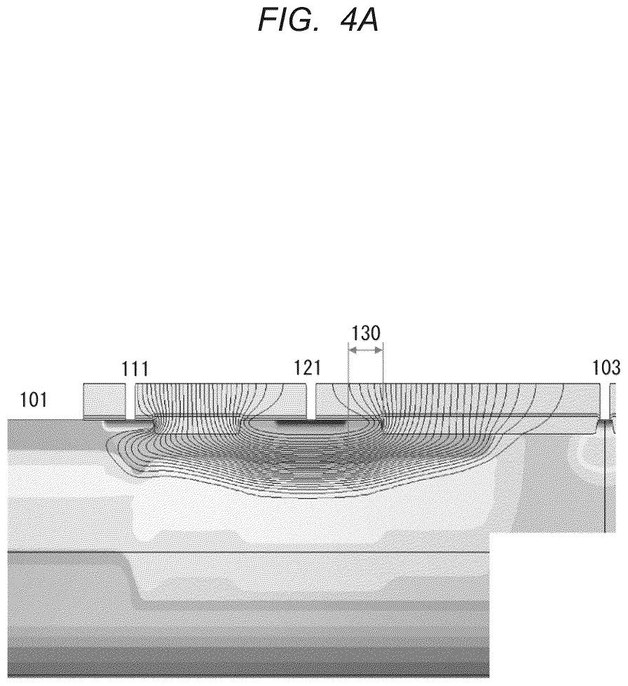

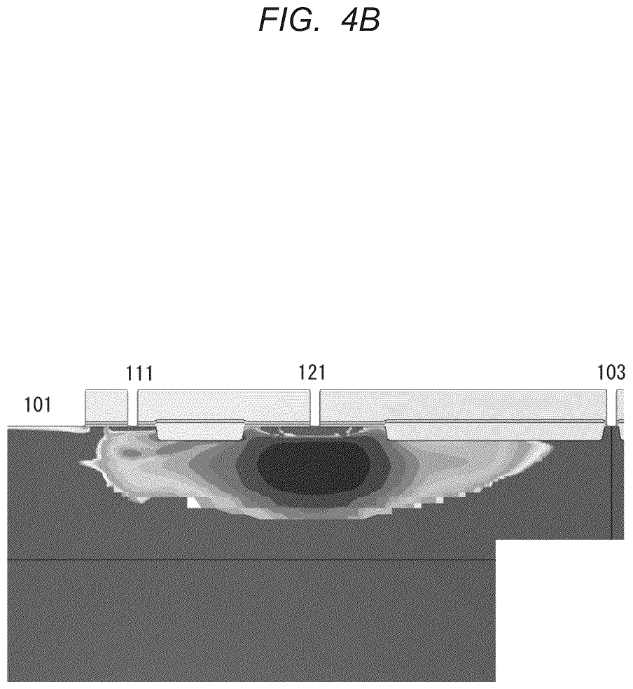

FIG. 4A shows the electrostatic potential map during reverse bias of the semiconductor device 1 of the present disclosure. FIG. 4B shows the distribution of impact ionization during reverse bias of the semiconductor device 1 of the present disclosure, i.e., the location of breakdown occurrence. As shown in FIG. 4A and FIG. 4B, the potential of the semiconductor device 1 of the present disclosure spreads in the depth direction, and it can be seen that the breakdown voltage of the SBD depends on the depth direction. In addition, in the first semiconductor region 101, the first region 111 and the first buried region 110 serve the function of a potential barrier. Therefore, even if the width of the offset region 130 is large, the effect of the potential barrier is maintained.

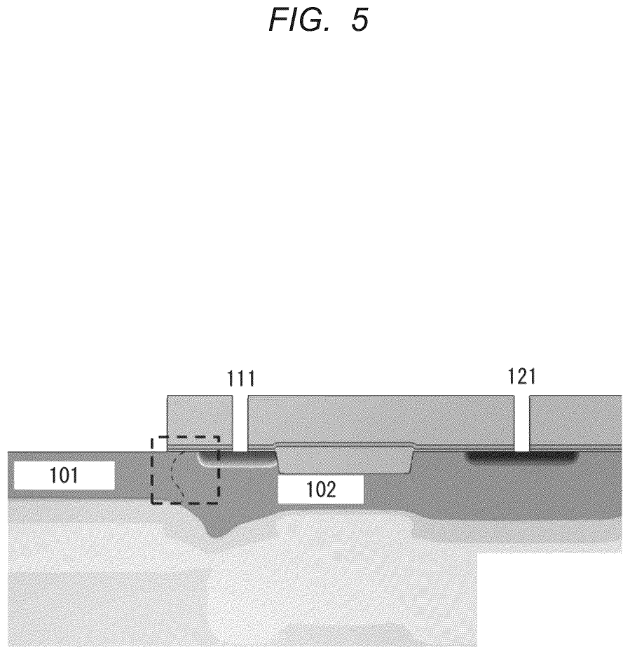

FIG. 5 shows the impurity concentration distribution of a semiconductor device of a comparative example. As shown in FIG. 5, in the semiconductor device of the comparative example, the second semiconductor region 102 extends beyond the first region 111 toward the first semiconductor region 101, which is a Schottky region (see the dotted line in FIG. 5). This is because impurities indicating the n-type, which is the second conductivity type, have diffused due to heat treatment when forming the second semiconductor region 102. In this case, it is undesirable because the second semiconductor region 102 comes into contact with the Schottky electrode (not shown).

In the simulation results of FIG. 5, when the width of the offset region 130 is 0.7 times or more the width of the first region 111, the second semiconductor region 102 extends beyond the first region 111 toward the first semiconductor region 101, which is a Schottky region.

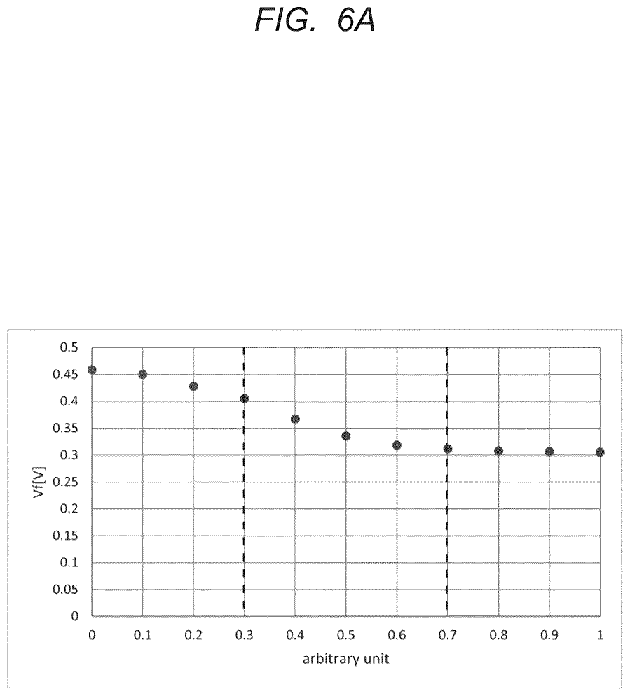

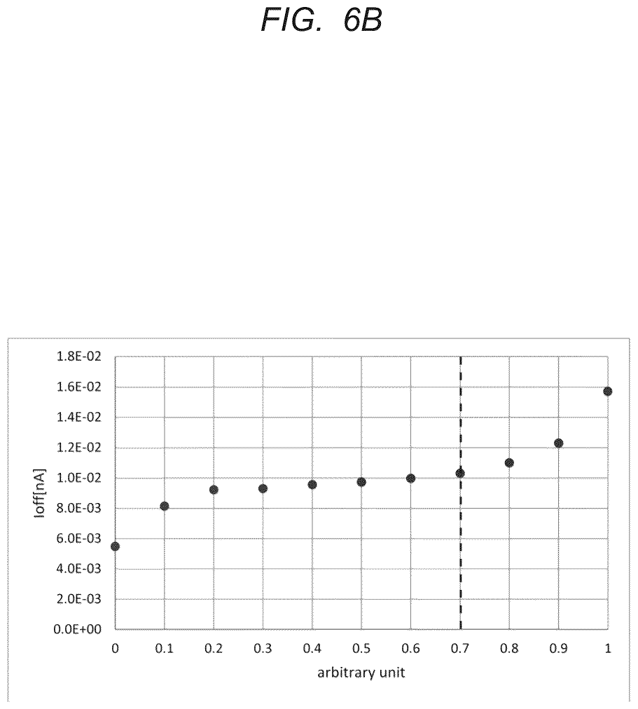

FIG. 6A shows the relationship between the width of the offset region 130 and the driving voltage. FIG. 6B shows the relationship between the width of the offset region 130 and the leakage current. Similar to the examples shown in FIG. 3A and FIG. 3B, the width of the first region 111 of the semiconductor device 1 is set to 1, and the width of the offset region 130 is varied from 0 to 1 to simulate the driving voltage and leakage current of the semiconductor device 1.

For example, as a specification value of the semiconductor device 1 of the present disclosure, the driving voltage is set to 0.4V. In this case, the SBD with the width of the offset region 130 being 0.3 times or more the width of the first region 111 meets the specifications. Also, as shown in FIG. 5, when the width of the offset region 130 is 0.7 times or more the width of the first region 111, the second semiconductor region 102 extends beyond the first region 111 toward the first semiconductor region 101, which is a Schottky region. Therefore, it is preferable that the width of the offset region 130 is in the range of 0.3 times or more and 0.7 times or less the width of the first region 111.

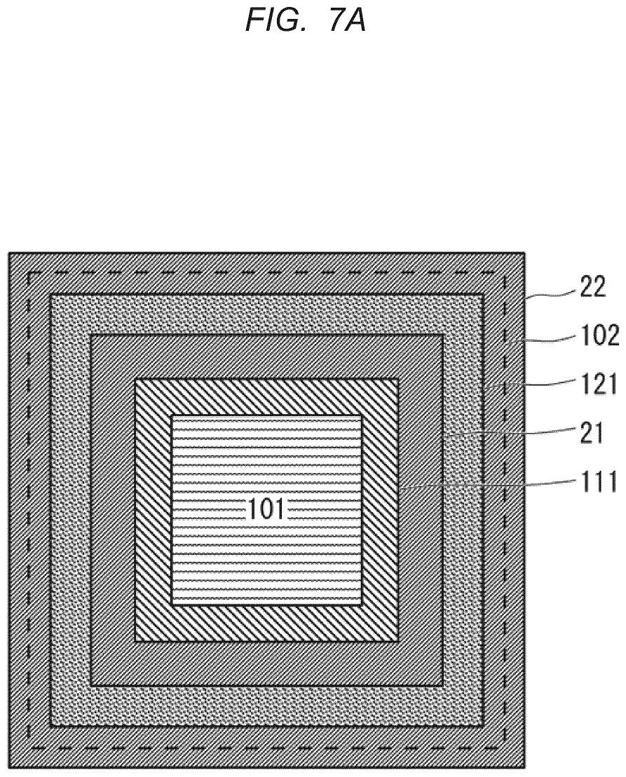

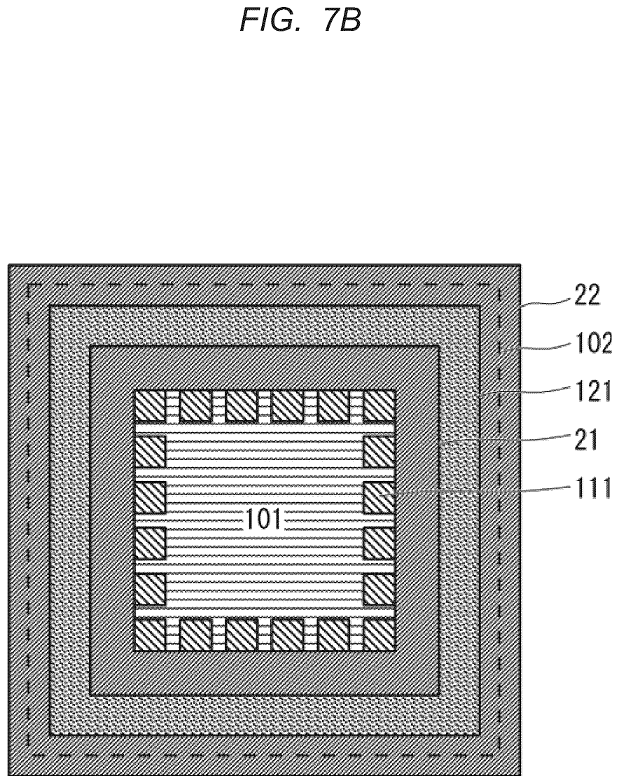

Next, FIG. 7A and FIG. 7B show a plan view of the region where the SBD of the semiconductor device 1 of the present disclosure is formed. FIG. 7A is a plan view of the semiconductor device 1 of the present disclosure, and FIG. 7B is a plan view of a modified example of the semiconductor device 1. For understanding, the second semiconductor region 102 is shown as a region enclosed by a dotted line.

As shown in FIG. 7A, the first region 111 surrounds a part of the first semiconductor region 101 in plan view. As shown in FIG. 2, the semiconductor device 1 may have an offset region 130 where the first region 111 and the second semiconductor region 102 overlap. At this time, the first region 111 also has a region overlapping the first semiconductor region 101.

Also, as shown in FIG. 7B, the first region 111 may have a plurality of patterns surrounding the first semiconductor region 101. At this time, it is preferable that each of the plurality of patterns of the first region 111 has square shape or rectangular shape.

The first insulating region 21 surrounds the first semiconductor region 101 and the first region 111 or a plurality of patterns of the first region 111. The cathode region 121 surrounds the first semiconductor region 101, the first region 111 or a plurality of patterns of the first region 111, and the first insulating region 21. The second insulating region 22 surrounds the first semiconductor region 101, the first region 111 or a plurality of patterns of the first region 111, the first insulating region 21, and the cathode region 121.

The second semiconductor region 102 surrounds the first semiconductor region 101 in plan view. Note that the second semiconductor region 102 overlaps the first region 111 or a plurality of patterns of the first region 111, the first insulating region 21, the cathode region 121, and the second insulating region 22, as shown in FIG. 2.

In this way, it is possible to provide a small-sized SBD that achieves high breakdown voltage, low driving voltage, and low leakage current.

### Second Embodiment

In the second embodiment, a modified example of the semiconductor device 1 of the first embodiment will be described. Note that the first embodiment and the second embodiment can be appropriately combined with each other, and repeated descriptions may be omitted for configurations similar to the configuration example of the first embodiment in the second embodiment.

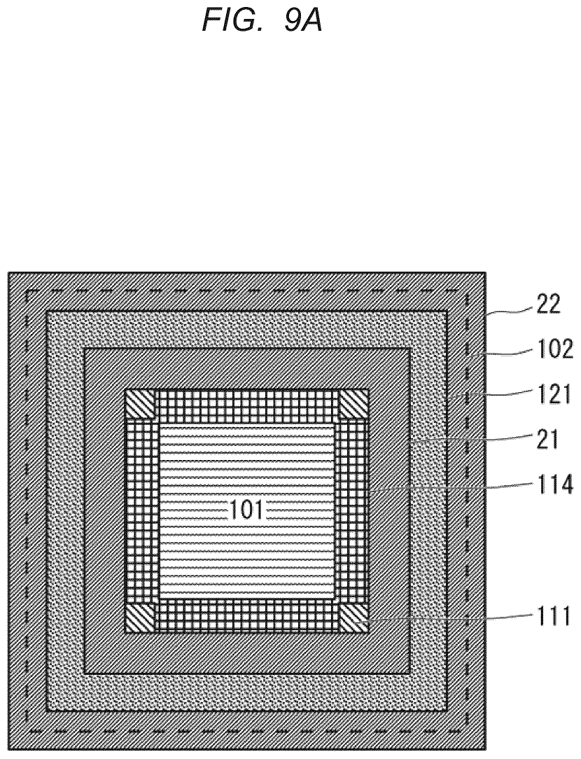

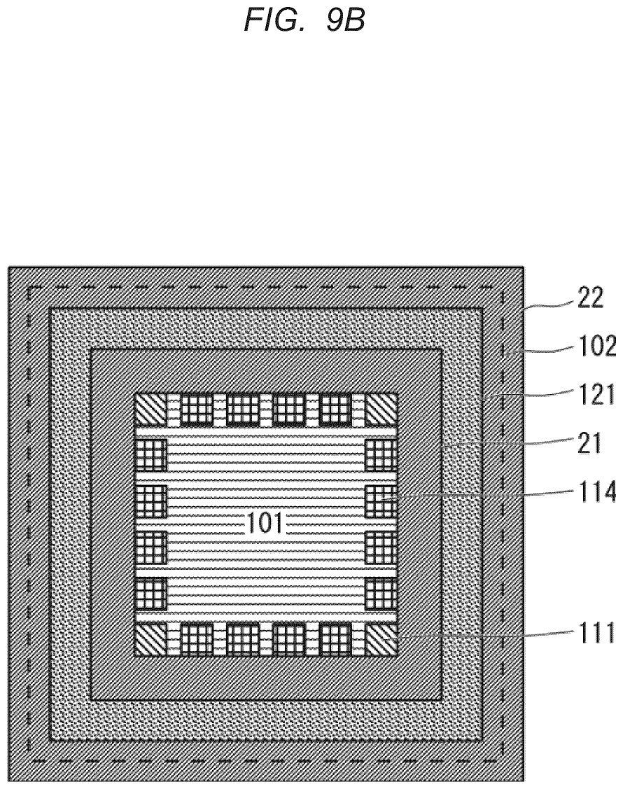

FIG. 18 is a cross-sectional view of the semiconductor device of the second embodiment. FIG. 9A and FIG. 9B are plan views of the semiconductor device 1 of the second embodiment. In the semiconductor device 1 of the second embodiment, a fourth region 114 having a p-type, which is the first conductivity type, is formed instead of the first region 111 of the semiconductor device 1 of the first embodiment. The impurity concentration of the fourth region 114 is higher than the impurity concentration of the first semiconductor region 101 and lower than the impurity concentration of the first region 111. That is, the fourth region 114 has a weaker potential barrier effect than the first region 111. With such a configuration, the width of the offset region 131 where the fourth region 114 and the second semiconductor region 102 overlap can be widened. Therefore, the process margin can be widened.

Note that in order to form the Schottky electrode, the fourth region 114 needs to form a region having an impurity concentration approximately the same as the impurity concentration of the first region 111. In the example shown in FIG. 9A, regions having an impurity concentration approximately the same as the impurity concentration of the first region 111 are formed at the four corners of the fourth region 114. For convenience, the regions at the four corners of the fourth region 114 shown in FIG. 9A and FIG. 9B are described as the first region 111. Also, in the example shown in FIG. 9B, the fourth region 114 has a plurality of patterns. Among the plurality of patterns of the fourth region 114, the corner patterns are formed as regions having an impurity concentration approximately the same as the impurity concentration of the first region 111.

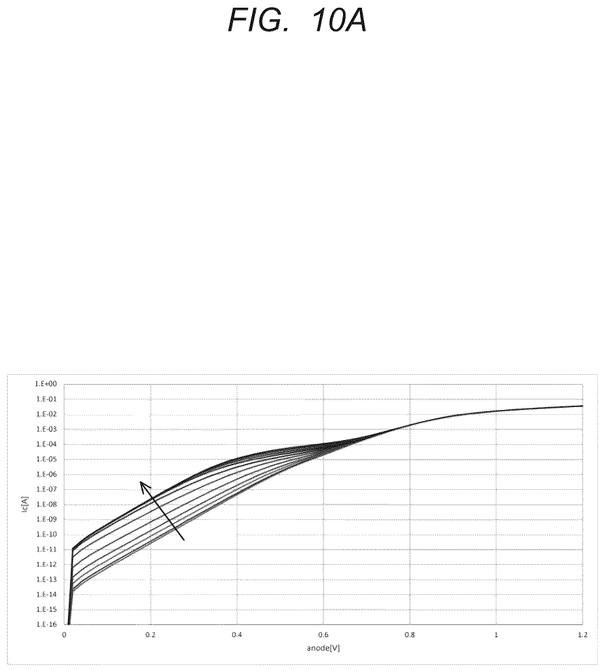

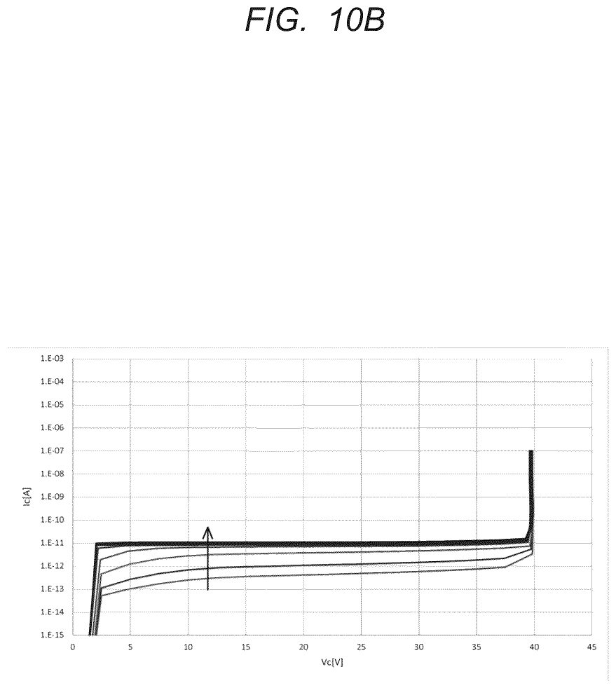

FIG. 10A shows the driving voltage of the semiconductor device 1 of the second embodiment, and FIG. 10B shows the off current, i.e., the leakage current, of the semiconductor device 1 of the second embodiment. FIG. 10A and FIG. 10B each represent the dependency of the offset amount of the driving voltage and the leakage current. The width of the fourth region 114 of the semiconductor device 1 is set to 1, and the width of the offset region 130 is varied from 0 to 1 to simulate the driving voltage and leakage current of the semiconductor device 1. The arrows in FIG. 10A and FIG. 10B indicate the direction in which the width of the offset region 130 increases from 0 to 1.

As shown in FIG. 10A, as the width of the offset region 130 increases, the driving voltage of the semiconductor device 1 decreases. On the other hand, as shown in FIG. 10B, as the width of the offset region 130 increases, the leakage current of the semiconductor device 1 increases.

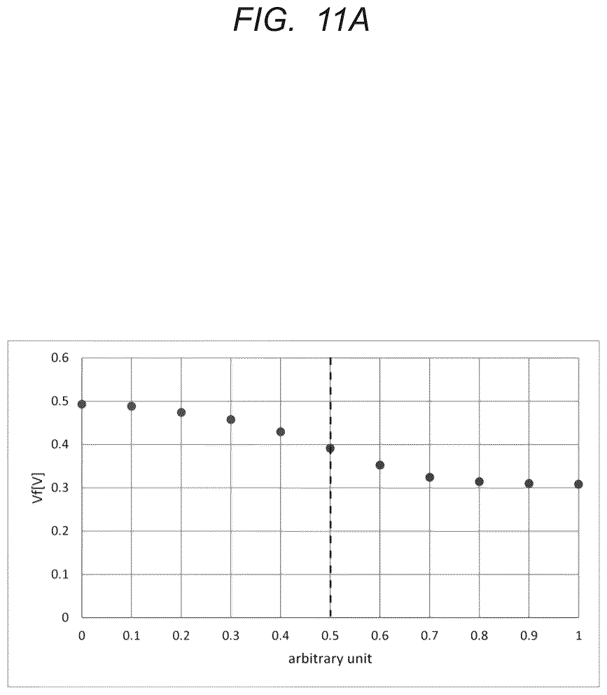

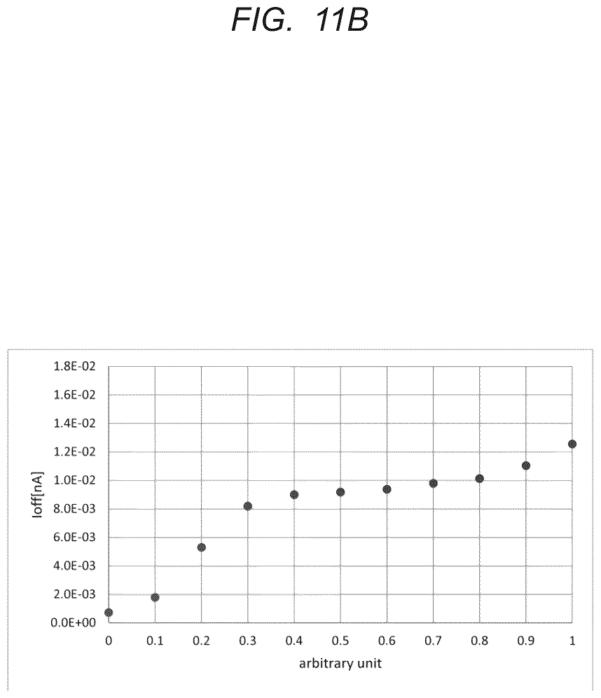

FIG. 11A shows the relationship between the width of the offset region 130 and the driving voltage. FIG. 11B shows the relationship between the width of the offset region 130 and the leakage current. Similar to the examples shown in FIG. 10A and FIG. 10B, the width of the fourth region 114 of the semiconductor device 1 is set to 1, and the width of the offset region 130 is varied from 0 to 1 to simulate the driving voltage and leakage current of the semiconductor device 1.

For example, as a specification value of the semiconductor device 1 of the second embodiment, the driving voltage is set to 0.4V. In this case, the SBD with the width of the offset region 130 being 0.5 times or more the width of the fourth region 114 meets the specifications. Note that if the width of the offset region 130 exceeds 1.0 times the width of the fourth region 114, the second semiconductor region 102 extends beyond the fourth region 114 toward the first semiconductor region 101. Therefore, it is understood that the width of the offset region 130 in the second embodiment is preferably in the range of 0.5 times to 1.0 times the width of the fourth region 114.

### Third Embodiment

In the third embodiment, a modified example of the semiconductor device 1 of the first and second embodiments will be described. It should be noted that the first to third embodiments can be appropriately combined with each other, and repetitive descriptions may be omitted for configurations similar to those of the first and second embodiments in the third embodiment.

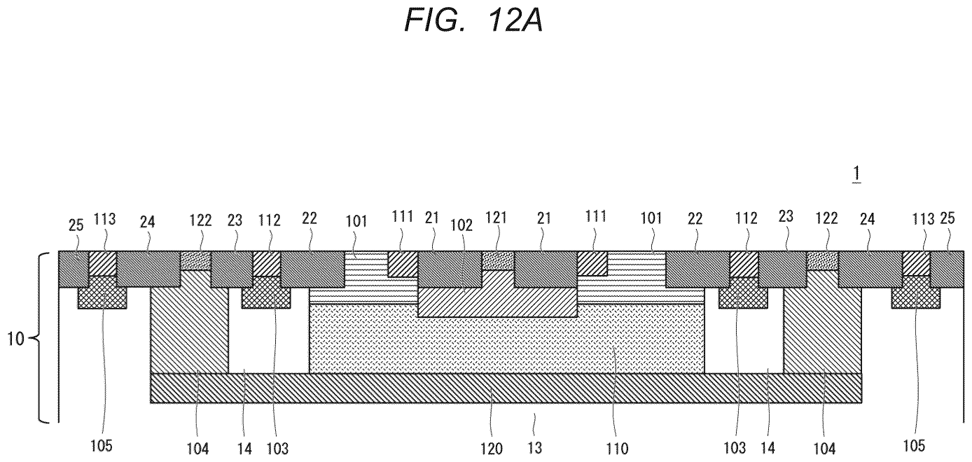

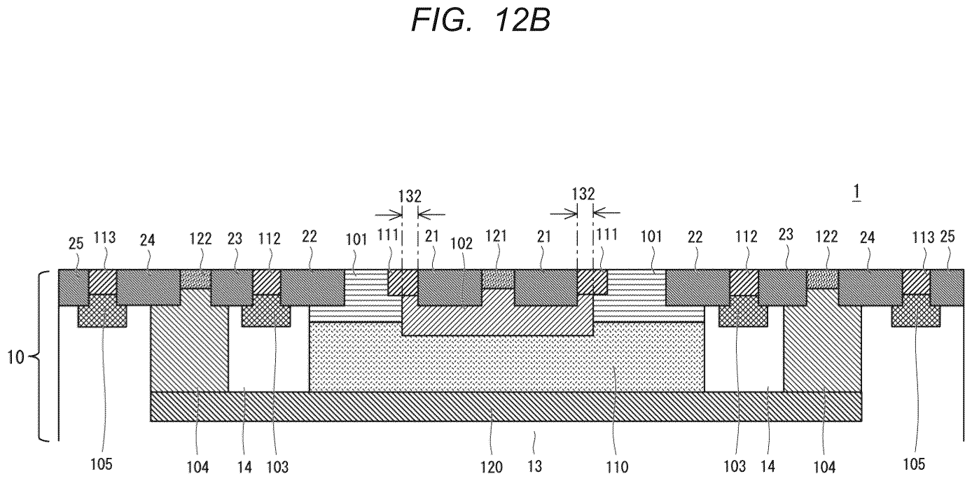

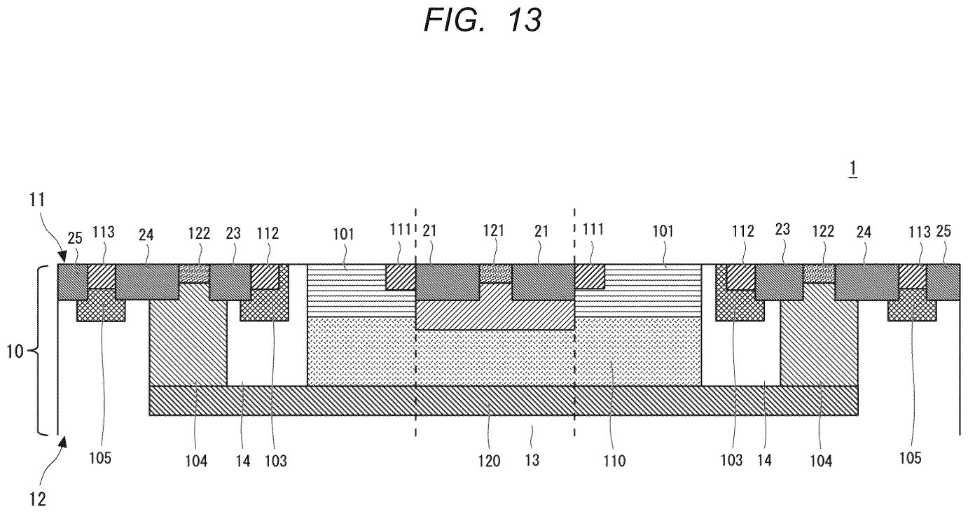

FIGS. 12A and 12B, as well as FIG. 13, are cross-sectional views of the semiconductor device 1 in the third embodiment. Unlike the semiconductor device 1 in the first and second embodiments, the semiconductor device 1 in the third embodiment has the first semiconductor region 101, which is a Schottky region, disposed outside the cathode region 121.

As shown in FIG. 12A, the first insulating region 21 is disposed to surround the cathode region 121. The first region 111 is disposed to surround the cathode region 121 and the first insulating region 21. The first semiconductor region 101 is disposed to surround the cathode region 121, the first insulating region 21, and a part of the first region 111.

Additionally, as shown in FIG. 12B, the second semiconductor region 102 may have an offset region 132 that overlaps the first region 111.

Furthermore, as shown in FIG. 13, the first semiconductor region 101, the third semiconductor region 103 functioning as a back gate electrode, and the second buried region 120 may be short-circuited without forming the second insulating region 22. With such a configuration, it is possible to suppress the operation of the parasitic NPN formed in the first semiconductor region 101, the third semiconductor region 103, and the second buried region 120.

### Fourth Embodiment

In the fourth embodiment, a modified example of the semiconductor device 1 from the first to third embodiments will be described. It should be noted that the first to fourth embodiments can be appropriately combined with each other, and repetitive descriptions may be omitted for configurations similar to those of the first to third embodiments in the fourth embodiment.

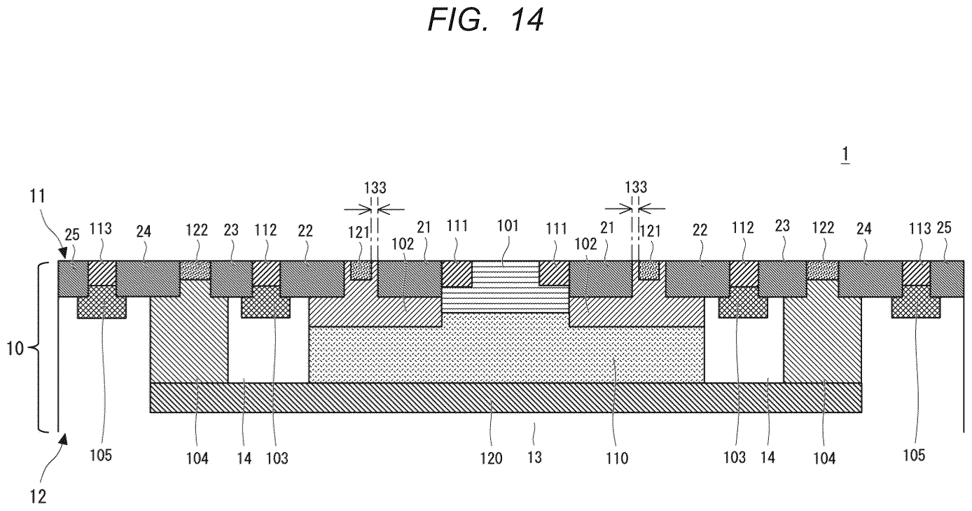

FIG. 14 shows a modified example in which the cathode region 121, disposed between the first insulating region 21 and the second insulating region 22, has an offset region 133. With such a configuration, the depletion layer at the corner of the first insulating region 21, functioning as STI, is expanded. Therefore, breakdown occurs at the PN junction rather than at the corner of the first insulating region 21, improving the reliability of the semiconductor device 1.

### Fifth Embodiment

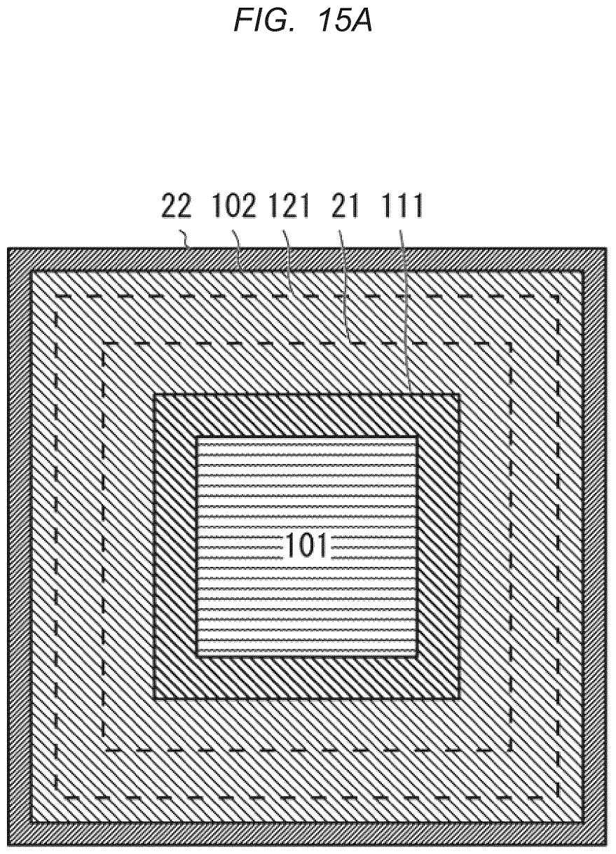

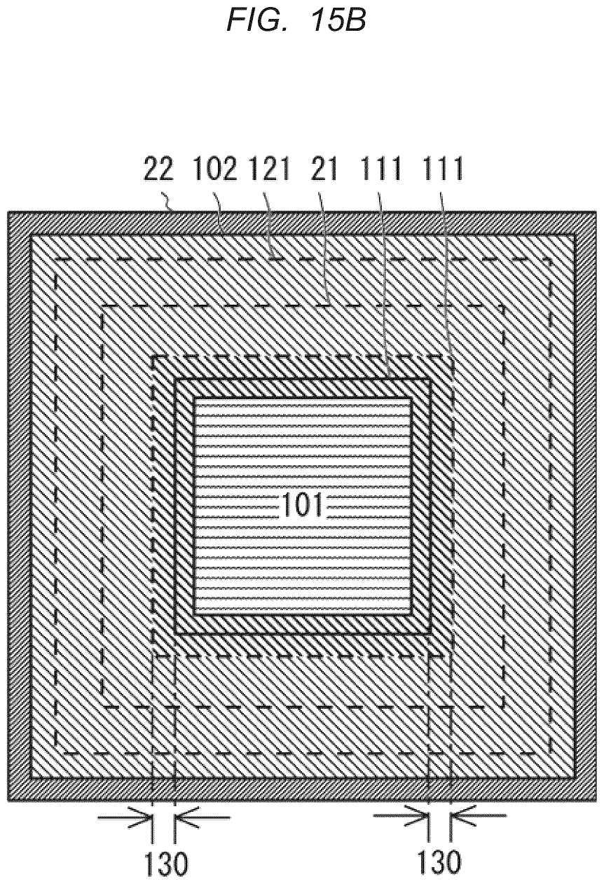

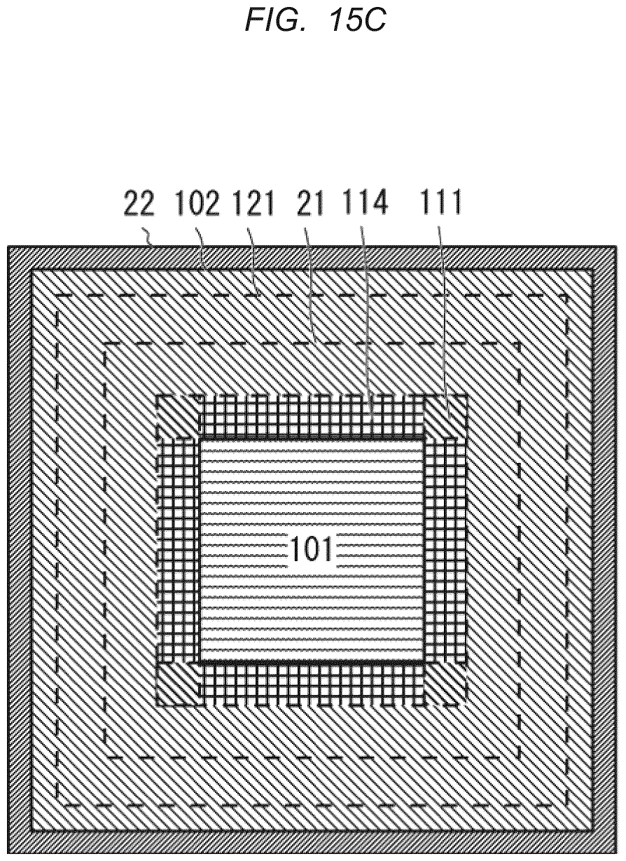

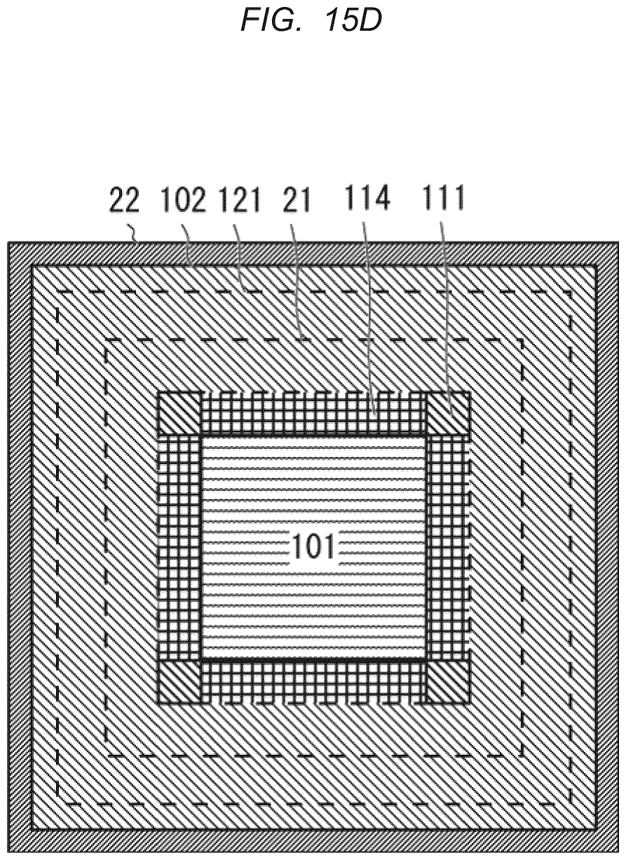

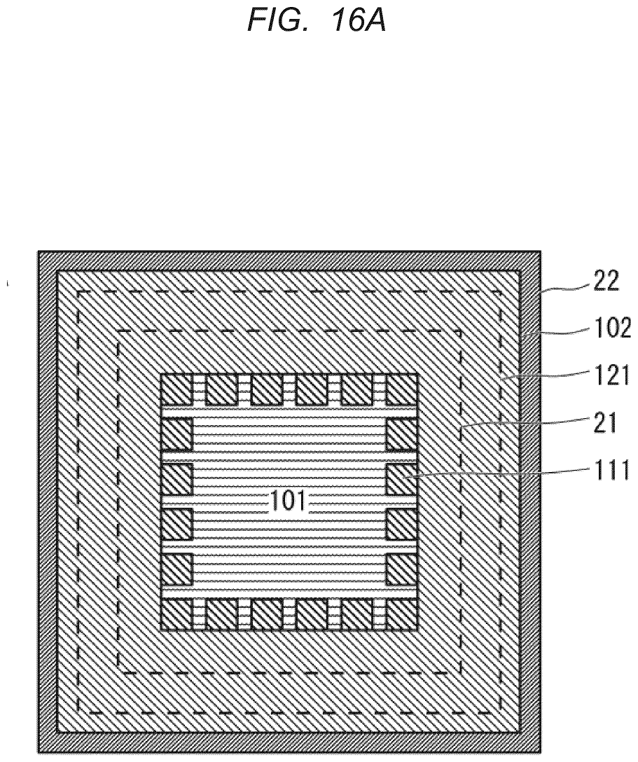

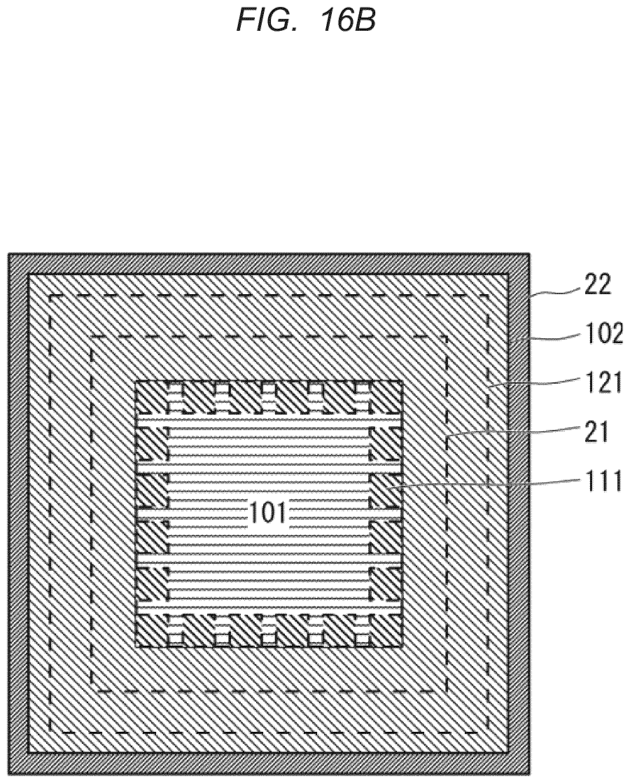

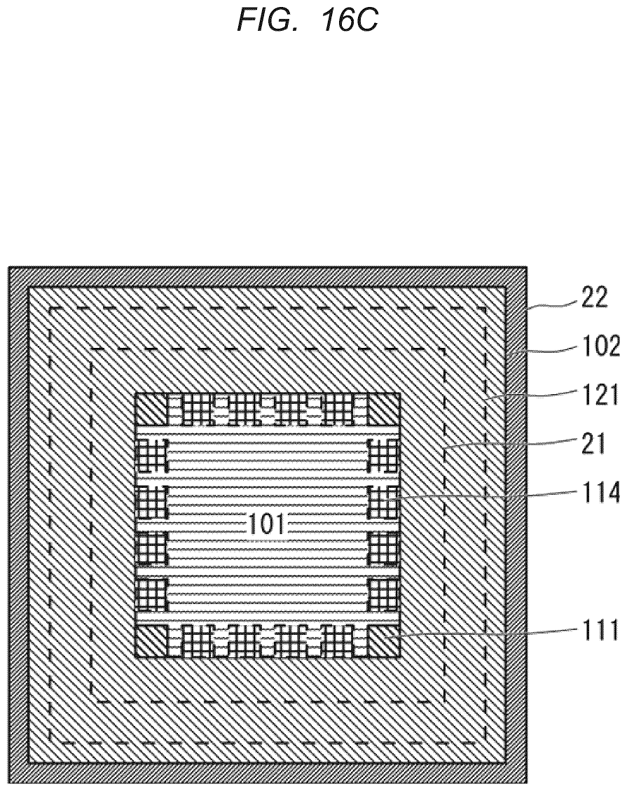

In the fifth embodiment, the positional relationship between the second semiconductor region 102 and the first region 111, which has the effect of a potential barrier, in the semiconductor device 1 from the first to fourth embodiments will be described using FIGS. 15A to 15D and FIGS. 16A to 16C. It should be noted that the plan views shown in FIGS. 15A to 15D and FIGS. 16A to 16C transparently show components other than the second semiconductor region 102 and the first region 111 with dotted lines.

FIG. 15A is a plan view of the semiconductor device 1 shown in FIGS. 1 and 7A. FIG. 15B is a plan view of the semiconductor device 1 shown in FIG. 2, and the second semiconductor region 102 has an offset region 130 that overlaps with the first region 111.

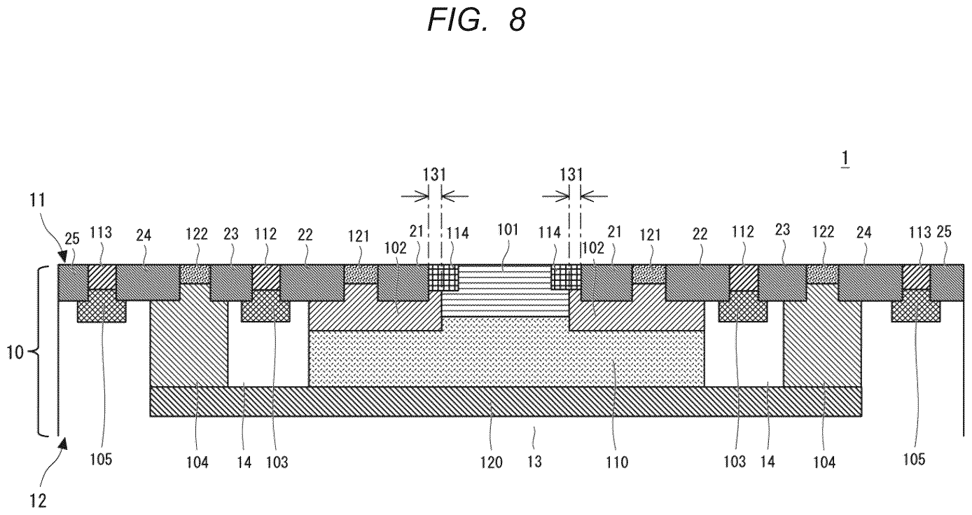

FIG. 15C is a plan view of the semiconductor device 1 shown in FIGS. 8 and 9A. In the configuration example shown in FIG. 15C, the first region 111 overlaps with the second semiconductor region 102. On the other hand, in the semiconductor device 1 shown in FIGS. 8 and 9A, the first region 111 and the second semiconductor region 102 may not overlap with each other, as shown in FIG. 15D. With such a configuration, it is possible to suppress the inhibition of ohmic contact between the first region 111 and the Schottky electrode due to the overlap of the first region 111 and the second semiconductor region 102.

FIGS. 16A to 16C are plan views of the semiconductor device 1 when the first region 111 has a plurality of patterns. FIG. 16A is a plan view of the semiconductor device 1 shown in FIGS. 1 and 7B, showing an example where a plurality of patterns of the first region 111 are exposed on the upper surface 11 of the semiconductor substrate 10. FIG. 16B is a modified example of the semiconductor device 1 shown in FIGS. 1 and 7B, showing an example where a plurality of patterns of the first region 111 overlap with the second semiconductor region 102.

FIG. 16C is a plan view of the semiconductor device 1 shown in FIGS. 8 and 9B. In the configuration example shown in FIG. 16C, the fourth region 114 overlaps with the second semiconductor region 102. On the other hand, the first region 111 and the second semiconductor region 102 do not overlap with each other. With such a configuration, it is possible to suppress the inhibition of ohmic contact between the first region 111 and the Schottky electrode due to the overlap of the first region 111 and the second semiconductor region 102.

Although the invention made by the inventors has been specifically described based on the embodiments, it is needless to say that the present disclosure is not limited to the embodiments already described, and various modifications can be made without departing from the gist thereof.

What is claimed is:

1. A semiconductor device, comprising:
a semiconductor substrate having an upper surface;
a first semiconductor region formed in the semiconductor substrate and at the upper surface of the semiconductor substrate;
a second semiconductor region formed in the semiconductor substrate;
a first buried region formed in the semiconductor substrate and disposed under the first semiconductor region and the second semiconductor region;
a first region formed in the first semiconductor region and disposed at the upper surface of the semiconductor substrate;
a cathode region formed in the second semiconductor region and disposed at the upper surface of the semiconductor substrate; and
a first insulating region formed in the semiconductor substrate and disposed between the first semiconductor region and the cathode region,
wherein an impurity concentration of the second semiconductor region is higher than an impurity concentration of the first semiconductor region,
wherein each of the semiconductor substrate, the first buried region, and the first region has a first conductivity type,
wherein each of the first semiconductor region, the second semiconductor region, and the cathode region has a second conductivity type opposite to the first conductivity type, and
wherein in cross-sectional view, the second semiconductor region reaches a side surface of the first insulating region facing the first semiconductor region.

2. The semiconductor device according to claim 1,
wherein the second semiconductor region surrounds the first semiconductor region in plan view,
wherein the first region surrounds a part of the first semiconductor region, and
wherein the first insulating region surrounds the first semiconductor region.

3. The semiconductor device according to claim 1,
wherein a depth of the second semiconductor region is greater than a depth of the first semiconductor region, when the upper surface of the semiconductor substrate is used as a reference plane.

4. The semiconductor device according to claim 1,
wherein a depth of the first region is greater than a depth of the cathode region, when the upper surface of the semiconductor substrate is used as a reference plane.

5. The semiconductor device according to claim 1,
wherein the first region is in contact with the first insulating region, and
wherein a part of the first semiconductor region is formed between the first region and the first buried region.

6. The semiconductor devoce according to claim 1,
wherein the second semiconductor region has an offset region overlapping the first region in plan view.

7. The semiconductor device according to claim 1,
wherein the first region in plan view has a plurality of patterns, and
wherein each of the plurality of patterns has square shape or rectangular shape.

8. The semiconductor device according to claim 7,
wherein the plurality of patterns include at least one of the first region and a plurality of fourth regions, and
wherein an impurity concentration of each of the plurality of fourth regions is lower than an impurity concentration of the first region and higher than the impurity concentration of the first semiconductor region.

9. The semiconductor device according to claim 1,
wherein a depth of the second semiconductor region is greater than a depth of the first semiconductor region, when the upper surface of the semiconductor substrate is used as a reference plane.

10. The semiconductor device according to claim 1,
wherein an impurity concentration of the first region is higher than an impurity concentration of the first semiconductor region, and
wherein an impurity concentration of the cathode region is higher than an impurity concentration of the second semiconductor region.

11. The semiconductor device according to claim 1,
wherein in plan view, a part of the second semiconductor region is formed between the cathode region and the first insulating region.

12. The semiconductor device according to claim 1, comprising:
a Schottky electrode formed on the first semiconductor region; and
a cathode electrode formed on the cathode region,
wherein the first semiconductor region and the second semiconductor region configure a Schottky barrier diode.

13. The semiconductor device according to claim 12, comprising:
a sinker region formed in the semiconductor substrate, the sinker region surrounding the first semiconductor region, the second semiconductor region, and the first buried region in plan view; and
a second buried region formed in the semiconductor substrate, the second buried region being disposed under the first buried region and the sinker region,
wherein the second buried region has the second conductivity type, and
wherein the Schottky barrier diode is surrounded by the second buried region and the sinker region.

14. The semiconductor device according to claim 1,
wherein the first semiconductor region surrounds the second semiconductor region in plan view,
wherein the first region surrounds a part of the second semiconductor region, and
wherein the first insulating region surrounds the cathode region.
